(19) United States
(12) Patent Application Publication
(10) Pub. No.: US 2023/0238235 A1
(43) Pub. Date: Jul. 27, 2023

(54) SEMICONDUCTOR DEVICE AND METHOD FOR MANUFACTURING SAME

(71) Applicant: CHANGXIN MEMORY TECHNOLOGIES, INC., Hefei City (CN)

(72) Inventor: Tao CHEN, Hefei (CN)

(21) Appl. No.: 17/746,452

(22) Filed: May 17, 2022

Related U.S. Application Data
(63) Continuation of application No. PCT/CN2022/078648, filed on Mar. 1, 2022.

(30) Foreign Application Priority Data
Jan. 21, 2022 (CN) 202210072561.7

(51) Int. Cl. H01L 21/02; H01L 29/10; H01L 21/28; H01L 29/51

(52) U.S. Cl. CPC H01L 21/02197; H01L 29/1079; H01L 21/28088; H01L 29/517; H01L 21/0237

(57) ABSTRACT

Embodiments of the present disclosure disclose a semiconductor device and a method for manufacturing the same. The semiconductor device includes: a substrate; a gate layer located on the substrate; a first conduction layer and a second conduction layer located on the gate layer and including a perovskite as the material thereof; a first source and a first drain spaced apart from each other and connected with either end of the first conduction layer respectively; a second source and a second drain spaced apart from each other and connected with either end of the second conduction layer respectively.

### CROSS-REFERENCE TO RELATED APPLICATION

This application is a U.S. continuation application of International Application No. PCT/CN2022/078648, filed on Mar. 1, 2022, which claims priority to Chinese Patent Application No. 202210072561.7, filed on Jan. 21, 2022. International Application No. PCT/CN2022/078648 and Chinese Patent Application No. 202210072561.7 are incorporated herein by reference in their entireties.

### TECHNICAL FIELD

The present disclosure relates to, but is not limited to, a semiconductor device and a method for manufacturing the same.

### BACKGROUND

In the manufacturing field of dynamic random access memory (DRAM), with the rapid development of advanced process technology (10 nm node and below), and under demands of faster switching speed and low power consumption, the control of short channel effect (SCE) on silicon-based MOS devices has become a major difficulty.

### SUMMARY

In view of this, embodiments of the present disclosure provide a semiconductor device and a method for manufacturing the same.

According to a first aspect of the embodiments of the present disclosure, a semiconductor device is provided. The semiconductor device includes: a substrate; a gate layer located on the substrate; a first conduction layer and a second conduction layer located on the gate layer and including a perovskite as a material; a first source and a first drain spaced apart from each other and connected with either end of the first conduction layer respectively; a second source and a second drain spaced apart from each other and connected with either end of the second conduction layer respectively.

According to a second aspect of the embodiments of the present disclosure, a method for manufacturing a semiconductor device is provided. The method includes the following operations.

A substrate is provided.

A gate layer is formed on the substrate.

A first conduction layer and a second conduction layer are formed on the gate layer. The materials of the first conduction layer and the second conduction layer include a perovskite.

A first source and a first drain that are spaced apart from each other are formed at and connected with either end of the first conduction layer, respectively.

A second source and a second drain that are spaced apart from each other are formed at and connected with either end of the second conduction layer, respectively.

### BRIEF DESCRIPTION OF THE DRAWINGS

In order to more clearly illustrate the embodiments of the present disclosure or the technical solutions in the related art, the drawings required in the embodiments will be briefly introduced below. Apparently, the drawings in the following description are only some embodiments of the present disclosure. Other drawings are also obtainable for those skilled in the art from these drawings without any creative effort.

FIG. 1 schematically shows a structure of a semiconductor device provided by an embodiment of the present disclosure.

FIG. 2 shows a top view of a semiconductor device provided by an embodiment of the present disclosure.

FIG. 3A shows a circuit diagram of an inverter in an embodiment of the present disclosure.

FIG. 3B schematically shows a structure corresponding to an inverter in an embodiment of the present disclosure.

FIG. 4 schematically shows a flowchart of a method for manufacturing a semiconductor device provided by an embodiment of the present disclosure.

FIGS. 5A to 5H schematically show structures during a method for manufacturing a semiconductor device provided by the embodiments of the present disclosure.

### DETAILED DESCRIPTION

Exemplary implementation modes of the present disclosure will be described in more detail below with reference to the accompanying drawings. While exemplary implementation modes of the present disclosure are shown in the drawings, it should be understood that the present disclosure may be implemented in various forms and should not be limited by the specific implementation modes set forth herein. Rather, these implementation modes are provided for more thoroughly understanding the present disclosure and fully conveying the scope of the present disclosure to those skilled in the art.

In the following description, numerous specific details are set forth in order to provide a more thorough understanding of the present disclosure. It will be apparent, however, to those skilled in the art that the present disclosure may be practiced without one or more of these details. In other examples, some technical features that are well known in the art have not been described in order to avoid obscuring the present disclosure. That is, not all features of an actual embodiment are described herein, and well-known functions and constructions are not described in detail.

In the drawings, the sizes of layers, regions, elements, and their relative sizes may be enlarged for clarity. The same reference numbers refer to the same elements throughout.

It should be understood that when an element or layer is referred to as being “on”, “adjacent to”, “connected to”, or “coupled to” another element or layer, it can be directly on, adjacent to, connected to or coupled to another element or layer, or intervening elements or layers may be present. Rather, when an element is referred to as being “directly on”, “directly adjacent to”, “directly connected to”, or “directly coupled to” another element or layer, there are no intervening elements or layers present. It should be understood that, although the terms “first”, “second”, “third”, etc. may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer, or part discussed below could be termed a second element, component, region, layer or part without departing from the teachings of the present disclosure. The discussion of a second element, component, region, layer or part does not imply that the first element, component, region, layer or part is necessarily present in the present disclosure.

Spatial relational terms such as “below”, “under”, “lower”, “beneath”, “above”, “upper”, etc., may be used herein for ease of description so as to describe the relationship between one element or feature and other elements or features shown in the figures. It should be understood that the spatial relational terms are intended to encompass different orientations of the device in use and operation in addition to the orientation shown in the figures. For example, if the device in the figures is turned over, elements or features described as being “below” or “under” or “beneath” other elements or features would then be oriented “above” the other elements or features. Thus, the exemplary terms “below” and “under” can encompass both orientations of above and below. The device may be otherwise oriented (rotated 90 degrees or at other orientations) and the spatial descriptors used herein are interpreted accordingly.

The terminology used herein is for the purpose of describing particular embodiments only and is not intended to be limiting of the present disclosure. As used herein, the singular forms “a”, “an”, and “said/the” are intended to include the plural forms as well, unless the context clearly dictates otherwise. It should also be understood that the terms “consist . . . of” and/or “include”, when used in this specification, determine the presence of said features, integers, steps, operations, elements and/or components, but do not exclude the presence or addition of one or more other features, integers, steps, operations, elements, components and/or groups. As used herein, the term “and/or” includes any and all combinations of the associated listed items.

For a thorough understanding of the present disclosure, detailed steps and detailed structures will be presented in the following description in order to explain the technical solutions of the present disclosure. Preferred embodiments of the present disclosure are described in detail below. However, the present disclosure may also have other embodiments in addition to these detailed descriptions.

In some embodiments, halo and lightly Doped Drain (LDD) doping techniques are mainly used to reduce SCE. The depth of ion implantation in the halo technique is greater than the depth of ion implantation in the lightly doped drain doping technique, effectively reducing the lateral expansion of the depletion regions of the source and drain regions, thereby avoiding the source-drain punch-through phenomenon. However, various doping techniques not only require high fabrication costs, but also increase the issue in term of device reliability, such as transient enhanced diffusion of boron, PN junction leakage, and negative bias temperature instability (NBTI). Ultra-thin-body (UTB), as an effective means to reduce SCE, enables the gate to better adjust the device. In UTB devices, the thickness of the channel generally needs to be controlled at ⅓ of the gate length. However, below the 10 nm node, the thickness inhomogeneity of the atomic size will increase the variation of the surface potential, resulting in enhanced carrier coulomb scattering, reduced carrier mobility, and reduced saturation current.

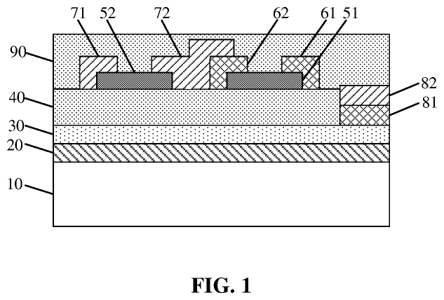

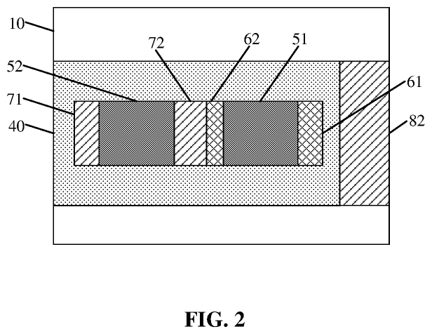

Based on this, embodiments of the present disclosure provide a semiconductor device. FIG. 1 schematically shows a structure of a semiconductor device provided by an embodiment of the present disclosure. FIG. 2 shows a top view of a semiconductor device provided by an embodiment of the present disclosure. It is noted that the top view in FIG. 2 is a plan view obtained after removing the passivation layer 90.

Referring to FIGS. 1 and 2, the semiconductor device includes a substrate 10; a gate layer 30 located on the substrate 10; a first conduction layer 51 and a second conduction layer 52 located on the gate layer 30, the materials of the first conduction layer 51 and the second conduction layer 52 including a perovskite; a first source 61 and a first drain 62 spaced apart from each other and connected with either end of the first conduction layer 51 respectively; a second source 71 and a second drain 72 spaced apart from each other and connected with either end of the second conduction layer 52 respectively.

In the embodiments of the present disclosure, by using a perovskite material to form the conduction layers, and forming different types of Schottky junctions through the perovskite contact with different metals, the operation of ion implantation is omitted, thereby reducing the use of photomasks, as well as steps and costs of the process. Moreover, by using the perovskite material, the SCE effect can be suppressed, the threshold voltage can be reduced, and the saturation current and device reliability can be improved without additional doping.

In an embodiment, the substrate 10 may be an elemental semiconductor material substrate (for example, a silicon (Si) substrate, a germanium (Ge) substrate), a compound semiconductor material substrate (for example, a silicon germanium (SiGe) substrate), or silicon-on-insulator (SOI) substrate, germanium-on-insulator (GeOI) substrate, or quartz or sapphire substrate, etc.

The semiconductor device further includes an oxide layer 20 on the substrate 10. The material of the oxide layer 20 includes, but is not limited to, silicon dioxide.

The oxide layer 20 may be a gate oxide layer. The oxide layer is located between the gate layer 30 and the substrate 10, and thus can provide sufficient electrical insulation between the gate layer 30 and the substrate 10 located therebelow to prevent a short circuit between the gate layer 30 and the substrate 10.

In an embodiment, the gate layer 30 is located on the substrate 10. Specifically, the gate layer 30 is located on the oxide layer 20.

In some embodiments, the material of the gate layer 30 may include graphene. The use of graphene as the material of the gate layer 30 can reduce the contamination of the dielectric layer caused by the metal electrodes and avoid the electrical degradation of the device caused by high temperature annealing.

In some other embodiments, conventional metal electrode materials may also be used for the gate layer 30, as long as the conventional metal electrode materials do not cause damage to the perovskite material during the annealing process.

The semiconductor device further includes a dielectric layer 40 located on the gate layer 30 and covering part of the gate layer 30.

The dielectric layer 40 is located between the gate layer and the first conduction layer, the second conduction layer, and between the first source, the first drain, and the second source, the second drain which are located above the gate layer, and can play the role of insulating isolation, to prevent the short circuit between the gate layer and the conduction layers and the short circuit between the sources/drains.

The dielectric layer 40 is a high-K dielectric layer. The material of the dielectric layer 40 includes at least one of dielectric materials such as hafnium dioxide, silicon dioxide, or aluminum oxide.

The first conduction layer 51 and the second conduction layer 52 are located on the gate layer 30. Specifically, the first conduction layer 51 and the second conduction layer 52 are located on the dielectric layer 40.

In an embodiment, the perovskite includes an inorganic perovskite. The inorganic perovskite material has the advantages of high carrier mobility, a strong stability and a simple manufacturing and the like. In addition, the inorganic perovskite material can form a P-type or N-type field effect transistor (FET) by contacting with metals having different work functions, without performing ion implantation. For example, regarding the inorganic perovskite material in contact with different metals, a P-type FET is formed when its valence band is matched with a high work function metal, and an N-type FET is formed when its conduction band is matched with a low work function metal, showing that it can be used as a perfect component of MOS device in DRAM. Therefore, the formation of conduction layers by using the inorganic perovskite material can better reduce the threshold voltage, increase the saturation current, and thus improve the reliability of the device. Moreover, the step of ion implantation is omitted, so the process steps are reduced, reducing the costs.

In some embodiments, the inorganic perovskite includes CsPbBrₓI₃₋ₓ, where 0<x<3. When using CsPbBrₓI₃₋ₓ (0<x<3) as an ultra-thin channel with a size of less than 1 nm, it can suppress the SCE effect of silicon-based MOS devices caused by size reduction, and does not require additional doping, which can reduce the threshold voltage, improve saturation current and device reliability.

In some other embodiments, Cs may be replaced by Rb or Fr, Pb may be replaced by Sn, while Br and I may be replaced by Cl.

In an embodiment, an inversion layer (not shown in the figure) is formed on a side of the first conduction layer 51 and the second conduction layer 52 close to the dielectric layer 40. The inversion layer forms a conductive channel, which is the reason for the conduction of the device.

In an embodiment, the semiconductor device further includes a first source 61 and a first drain 62 that are spaced apart from each other and are connected with either end of the first conduction layer 51 respectively; a second source 71 and a second drain 72 that are spaced from each other and are connected with either end of the second conduction layer 52 respectively.

The first source 61, the first drain 62, the second source 71, and the second drain 72 are all located on the dielectric layer 40.

The first source 61 and the first drain 62 are located at either end of the first conduction layer 51 respectively, cover sidewalls of the first conduction layer 51, and are partially located on the first conduction layer 51.

The second source 71 and the second drain 72 are located at either end of the second conduction layer 52 respectively, cover sidewalls of the second conduction layer 52, and are partially located on the second conduction layer 52.

In some embodiments, the second drain 72 is in contact with the first drain 62, covers a sidewall of the first drain 62, and is partially located on the first drain 62.

In some other embodiments, the first drain 62 covers a sidewall of the second drain 72, and is partially located on the second drain 72. It should be noted that whether the first drain 62 covers the sidewall of the second drain 72 or the second drain 72 covers the sidewall of the first drain 62, it is necessary to ensure a good contact between the first drain 62 and the second drain 72.

In an embodiment, the first source 61, the first drain 62, the first conduction layer 51, and part of the gate layer 30 constitute a transistor of a first conductive type. The second source 71, the second drain 72, the second conduction layer 52, and part of the gate layer 30 constitute a transistor of a second conductive type. The first drain 62 is in contact with the second drain 72 contact, so that the transistor of the first conductive type and the transistor of the second conductive type constitute an inverter.

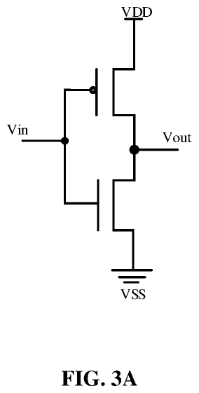

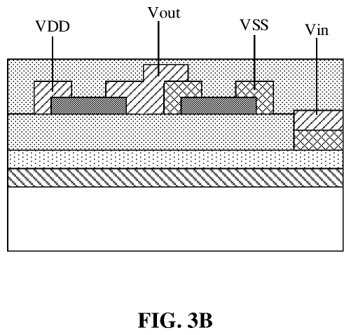

FIG. 3A shows a circuit diagram of an inverter in an embodiment of the present disclosure, and FIG. 3B schematically shows a structure corresponding to the inverter in an embodiment of the present disclosure. As shown in FIGS. 3A and 3B, the gate of the transistor of the first conductive type is connected with the gate of the transistor of the second conductive type, and serves as an input terminal Vin. The source of the transistor in the second conductive type, i.e., the second source, is connected to a power supply voltage VDD. The source of the transistor of the first conductive type, i.e., the first source, is grounded VSS. The drain of the transistor of the first conductive type is connected with the drain of the transistor of the second conductive type, and serves as an output terminal Vout. Specifically, the output terminal is led out through the second drain 72. Such a connection method only occupies a small area, and is more conducive to large-scale integration.

In this embodiment, the transistor of the first conductive type and the transistor of the second conductive type share one gate, so the integration is higher. Furthermore, only one gate is required to be fabricated, so the cost thereof is lower.

In an embodiment, the first conductive type is an N-type, and the second conductive type is a P-type. That is, the transistor of the first conductive type may be an NMOS transistor, and the transistor of the second conductive type may be a PMOS transistor.

In an embodiment, the materials of the first source 61 and the first drain 62 include a low work function material. The materials of the second source 71 and the second drain 72 include a high work function material. The low work function material has a lower work function, and the first conduction layer 51 is matched with the low work function material to form an NMOS transistor. The high work function material has a higher work function, and the second conduction layer 52 is matched with the high work function material to form a PMOS transistor. Both the low work function material and the high work function material are electrode materials.

Specifically, the low work function material includes a material such as Ti, Al, Ag, or Zn. The high work function material includes a material such as Au, Pt, C, W, Co, or Ni. In the embodiments of the present disclosure, the low work function material may be Ti, and the high work function material may be Au.

In an embodiment, a first metal layer 81 and a second metal layer 82 that are stacked, are formed on the part of the gate layer 30 not covered by the dielectric layer 40. The material of the first metal layer 81 is the same as that of the first source 61 and the first drain 62. The material of the second metal layer 82 is the same as that of the second source 71 and the second drain 72. The gate layer 30 is connected with the first metal layer 81 and the second metal layer 82, so that the PMOS transistor and the NMOS transistor share one gate layer.

In some embodiments, the thickness of the first metal layer 81 is equal to the thickness of the first source 61 and the thickness of the first drain 62, and the thickness of the second metal layer 82 is equal to the thickness of the second source 71. When they have the same thicknesses, the first metal layer and the first source and the first drain, or the second metal layer and the second source can be formed in the same deposition step.

In some other embodiments, the thickness of the first metal layer 81 may not be equal to the thickness of the first source 61 and the thickness of the first drain 62, and the thickness of the second metal layer 82 may not be equal to the thickness of the second source 71.

In an embodiment, the semiconductor device further includes a passivation layer 90 covering exposed surfaces of the first source 61, the first drain 62, the first conduction layer 51, the second source 71, the second drain 72, the second conduction layer 52 and the second metal layer 82. The passivation layer 90 can protect the channel material to prevent the channel material from being oxidized.

The passivation layer 90 is a high-K dielectric layer. The material of the passivation layer 90 includes at least one of dielectric materials such as hafnium dioxide, silicon dioxide, or aluminum oxide.

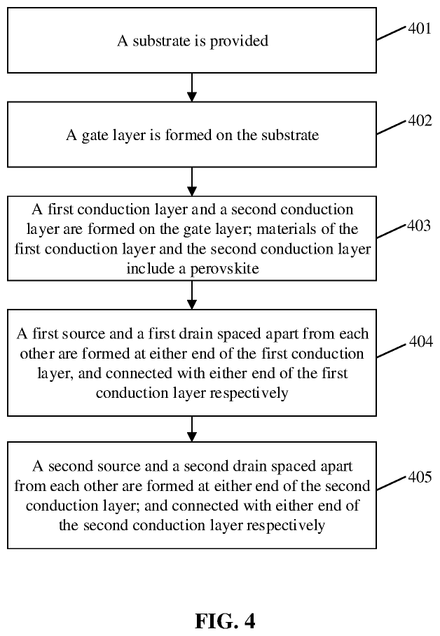

Embodiments of the present disclosure further provide a method for manufacturing a semiconductor device. Referring to FIG. 4 for details, the method includes the following steps as shown in the figure.

At step 401, a substrate is provided.

At step 402, a gate layer is formed on the substrate.

At step 403, a first conduction layer and a second conduction layer are formed on the gate layer. The materials of the first conduction layer and the second conduction layer include a perovskite.

At step 404, a first source and a first drain spaced apart from each other are formed at and connected with at either end of the first conduction layer, respectively.

At step 405, a second source and a second drain spaced apart from each other are formed at and connected with either end of the second conduction layer respectively.

The method for manufacturing a semiconductor device provided by the embodiments of the present disclosure will be further described in detail below with reference to specific embodiments.

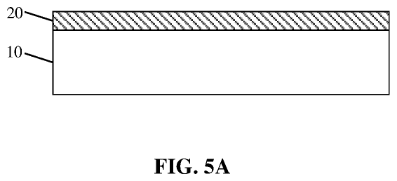

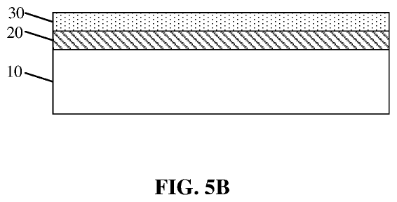

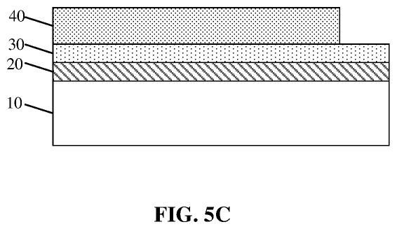

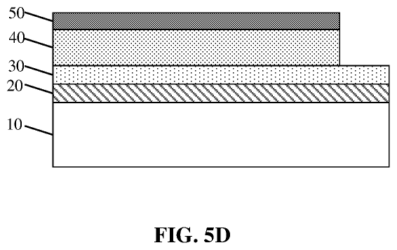

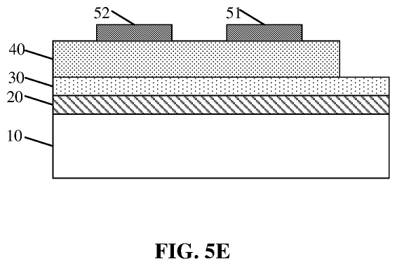

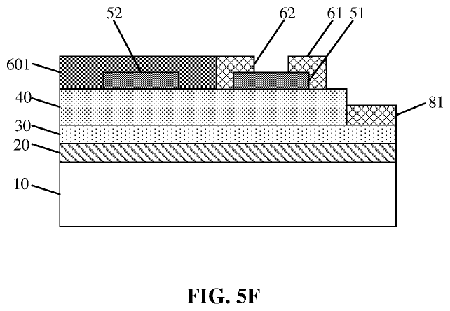

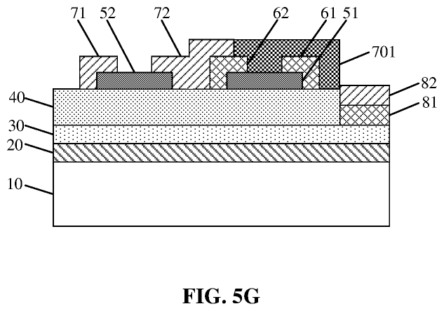

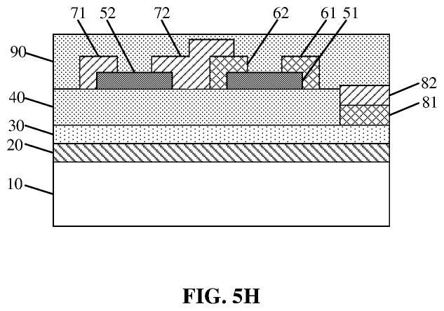

FIGS. 5A to 5H schematically show structures during a method for manufacturing a semiconductor device provided in the embodiments of the present disclosure.

First, referring to FIG. 5A, step 401 is performed, at which a substrate 10 is provided.

The substrate 10 may be an elemental semiconductor material substrate (for example, a silicon (Si) substrate, a germanium (Ge) substrate.), a compound semiconductor material substrate (for example, a silicon germanium (SiGe) substrate), or silicon on insulator (SOI) substrate, germanium on insulator (GeOI) substrate, or quartz or sapphire substrate, etc.

Referring to FIG. 5A again, an oxide layer 20 is formed on the substrate 10. The material of the oxide layer 20 includes, but is not limited to, silicon dioxide.

The oxide layer 20 may be a gate oxide layer. The oxide layer is located between the gate layer 30 and the substrate 10, and thus can provide sufficient electrical insulation between the gate layer 30 and the substrate 10 located therebelow to prevent a short circuit short between the gate layer 30 and the substrate 10.

Next, referring to FIG. 5B, step 402 is performed. A gate layer 30 is formed on the substrate 10. Specifically, the gate layer 30 is formed on the oxide layer 20.

In actual operation, the gate layer 30 may be formed by using a wet transfer or other deposition processes, including but not limited to a chemical vapor deposition (CVD) process, plasma enhanced chemical vapor deposition (PECVD) process, an atomic layer deposition (ALD) process, or a combination thereof.

In some embodiments, the material of the gate layer 30 may include graphene. The use of graphene as the material of the gate layer 30 can reduce the contamination of the dielectric layer caused by the metal electrodes and avoid the electrical degradation of the device caused by high temperature annealing.

In some other embodiments, conventional metal electrode materials may also be used for the gate layer 30, as long as the conventional metal electrode materials do not cause damage to the perovskite material during the annealing process.

Next, referring to FIG. 5C, the method further includes an operation of forming a dielectric layer 40 covering part of the gate layer 30 on the gate layer 30, after the gate layer 30 is formed.

The dielectric layer 40 is located between the gate layer and the first conduction layer, the second conduction layer, and between the first source, the first drain, and the second source, the second drain that are located above the gate layer, and can play the role of insulating isolation, to prevent the short circuit between the gate layer and the conduction layers and the short circuit between the sources/drains.

In actual operation, the dielectric layer 40 may be formed by one or more thin film deposition processes. Specifically, the deposition processes include but are not limited to a chemical vapor deposition (CVD) process, plasma enhanced chemical vapor deposition (PECVD) process, an atomic layer deposition (ALD) process, or a combination thereof.

The dielectric layer 40 is a high-K dielectric layer. The material of the dielectric layer 40 includes at least one of dielectric materials such as hafnium dioxide, silicon dioxide, or aluminum oxide.

Next, referring to FIG. 5D and FIG. 5E, step 403 is performed. A first conduction layer 51 and a second conduction layer 52 are formed on the gate layer 30. The materials of the first conduction layer 51 and the second conduction layer 52 include perovskite. Specifically, the first conduction layer 51 and the second conduction layer 52 are formed on the dielectric layer 40.

In actual operation, referring to FIG. 5D first, a pre-conductive layer 50 covering the dielectric layer 40 is formed on the dielectric layer 40.

The pre-conductive layer 50 may be formed through deposition by processes such as electron beam evaporation or blade coating, and may also be formed by one or more thin film deposition processes. Specifically, the deposition processes include but are not limited to a chemical vapor deposition (CVD) process, plasma enhanced chemical vapor deposition (PECVD) process, an atomic layer deposition (ALD) process, or a combination thereof.

Next, referring to FIG. 5E, the pre-conduction layer 50 is etched to form the first conduction layer 51 and the second conduction layer 52.

Specifically, a mask layer may be grown on the upper surface of the dielectric layer 40 first, and then the mask layer may be patterned, so as to display on the mask layer a pattern to be etched other than the first conduction layer and the first conduction layer. The mask layer may be patterned by a photolithography process. The mask layer may be a photoresist mask or a hard mask patterned based on a photolithography mask. When the mask layer is a photoresist mask, the mask layer is patterned specifically by operations such as exposing, developing, and degumming. Then, the part of pre-conduction layer to be removed is etched according to the pattern to be etched to form the first conduction layer and the second conduction layer.

The etching process may be a dry etching or a wet etching process. Specifically, the etching process may be a reactive ion etching (RIE) process, a plasma etching (Plasma Etching) process, or the like.

In an embodiment, the perovskite includes an inorganic perovskite. The inorganic perovskite material has the advantages of high carrier mobility, a strong stability and a simple manufacturing and the like. In addition, the inorganic perovskite material can form a P-type or N-type field effect transistor (FET) by contacting with metals having different work functions, without performing ion implantation. For example, regarding the inorganic perovskite material in contact with different metals, a P-type FET is formed when its valence band is matched with a high work function metal, and an N-type FET is formed when its conduction band is matched with a low work function metal, showing that it can be used as a perfect component of MOS device in DRAM. Therefore, the formation of conduction layers by using the inorganic perovskite material can better reduce the threshold voltage, increase the saturation current, and thus improve the reliability of the device. Moreover, the step of ion implantation is omitted, so the process steps are reduced, reducing the costs.

In some embodiments, the inorganic perovskite includes CsPbBrₓI₃₋ₓ, where 0<x<3. When using CsPbBrₓI₃₋ₓ (0<x<3) as an ultra-thin channel with a size of less than 1 nm, it can suppress the SCE effect of silicon-based MOS devices caused by size reduction, and does not require additional doping, which can reduce the threshold voltage, improve saturation current and device reliability.

In some other embodiments, Cs may be replaced by Rb or Fr, Pb may be replaced by Sn, while Br and I may be replaced by Cl.

In an embodiment, an inversion layer (not shown in the figure) is formed on a side of the first conduction layer 51 and the second conduction layer 52 close to the dielectric layer 40. The inversion layer forms a conductive channel, which is the reason for the conduction of the device.

Next, referring to FIG. 5F, step 404 is performed. A first source 61 and a first drain 62 that are spaced apart from each other are formed at either end of the first conduction layer 51. The first source 61 and the first drain 62 are connected with either end of the first conduction layer 51 respectively.

Specifically, a first photoresist layer 601 is formed on the second conduction layer and the part of the dielectric layer 40 where the first source and the first drain do not need to be formed. Then, the first source 61 and the first drain 62 are respectively formed at either side of the first conduction layer 51. The first source 61 and the first drain 62 cover the sidewall of the first conduction layer 51 and are partially located on the first conduction layer 51. After forming the first source 61 and the first drain 62, the first photoresist layer 601 is removed.

Referring to FIG. 5F again, in the same step of forming the first source 61 and the first drain 62, a first metal layer 81 is formed on the part of the gate layer 30 not covered by the dielectric layer 40. The material of the first metal layer 81 is the same as the material of the first source 61 and the first drain 62.

Next, referring to FIG. 5G, step 405 is performed. A second source 71 and a second drain 72 that are spaced apart from each other are formed at either end of the second conduction layer 52. The second source 71 and the second drain 72 are connected with either end of the second conduction layer 52 respectively.

Specifically, a second photoresist layer 701 is formed on the part of the dielectric layer 40 where the second source and the second drain do not need to be formed, the first conduction layer, the first source and a part of the first drain. Then, the second source 71 and the second drain 72 are respectively formed on either side of the second conduction layer 52. The second source 71 and the second drain 72 cover the sidewall of the second conduction layer 52 and are partially located on the second conduction layer 52. After the second source 71 and the second drain 72 are formed, the second photoresist layer 701 is removed.

In some embodiments, the second drain 72 is in contact with the first drain 62, covers the sidewall of the first drain 62, and is partially located on the first drain 62.

In some other embodiments, the first drain 62 covers the sidewall of the second drain 72, and is partially located on the second drain 72. It should be noted that whether the first drain 62 covers the sidewall of the second drain 72 or the second drain 72 covers the sidewall of the first drain 62, it is necessary to ensure a good contact between the first drain 62 and the second drain 72.

Referring to FIG. 5G again, in the same step of forming the second source 71 and the second drain 72, a second metal layer 82 is formed on the first metal layer 81. The material of the second metal layer 82 is the same as that of the second source 71 and the second drain 72.

In some embodiments, the thickness of the first metal layer 81 is equal to the thickness of the first source 61 and the first drain 62, and the thickness of the second metal layer 82 is equal to the thickness of the second source 71. When they have the same thickness, the first metal layer, the first source and the first drain, or the second metal layer and the second source can be formed in a same deposition step.

In some other embodiments, the thickness of the first metal layer 81 may not be equal to the thickness of the first source 61 and the first drain 62, and the thickness of the second metal layer 82 may not be equal to the thickness of the second source 71.

In one embodiment, the first source 61, the first drain 62, the first conduction layer 51 and part of the gate layer 30 constitute a transistor of a first conductive type. The second source 71, the second drain 72, the second conduction layer 52 and part of the gate layer 30 constitute a transistor of a second conductive type. The first drain 62 is in contact with the second drain 72, so that the transistor of the first conductive type and the transistor of the second conductive type constitute an inverter. In the embodiments of the present disclosure, the gate layer 30 is connected with the first metal layer 81 and the second metal layer 82, so that the transistor of the first conductive type and the transistor of the second conductive type share one gate layer.

FIG. 3A shows a circuit diagram of an inverter in an embodiment of the present disclosure, and FIG. 3B schematically shows a structure corresponding to the inverter in an embodiment of the present disclosure. As shown in FIGS. 3A and 3B, the gate of the transistor of the first conductive type is connected with the gate of the transistor of the second conductive type, and serves as an input terminal Vin. The source of the transistor of the second conductive type, i.e., the second source, is connected to the power supply voltage VDD. The source of the transistor of the first conductive type, i.e., the first source, is grounded VSS. The drain of the transistor of the first conductive type is connected with the drain of the transistor of the second conductive type, and serves as an output terminal Vout. Specifically, the output terminal is led out through the second drain 72. Such a connection method only occupies a small area, and is more conducive to large-scale integration.

In this embodiment, the transistor of the first conductive type and the transistor of the second conductive type share one gate, so the integration is higher. Furthermore, only one gate is required to be fabricated, so the cost thereof is lower.

In an embodiment, the first conductive type is an N-type, and the second conductive type is a P-type. That is, the transistor of the first conductive type may be an NMOS transistor, and the transistor of the second conductive type may be a PMOS transistor.

In an embodiment, the materials of the first source 61 and the first drain 62 include a low work function material. The materials of the second source 71 and the second drain 72 include a high work function material. The low work function material has a lower work function, and the first conduction layer is matched with the low work function material to form an NMOS transistor. The high work function material has a higher work function, and the second conduction layer is matched with the high work function material to form a PMOS transistor. Both the low work function material and the high work function material are electrode materials.

Specifically, the low work function material includes materials such as Ti, Al, Ag, or Zn. The high work function material includes materials such as Au, Pt, C, W, Co, or Ni. In the embodiments of the present disclosure, the low work function material may be Ti, and the high work function material may be Au.

Next, referring to FIG. 5H, the method further includes an operation of forming a passivation layer 90, after the second source 71 and the second drain 72 are formed. The passivation layer 90 covers exposed surfaces of the first source 61, the first drain 62, the first conduction layer 51, the second source 71, the second drain 72, the second conduction layer 52 and the second metal layer 82. The passivation layer can protect the channel material to prevent the channel material from being oxidized.

The passivation layer 90 is a high-K dielectric layer. The material of the passivation layer 90 includes at least one of dielectric materials such as hafnium dioxide, silicon dioxide, or aluminum oxide.

In actual operation, the passivation layer 90 may be formed by one or more thin film deposition processes. Specifically, the deposition processes include but are not limited to a chemical vapor deposition (CVD) process, plasma enhanced chemical vapor deposition (PECVD) process, an atomic layer deposition (ALD) process, or a combination thereof.

The above are only preferred embodiments of the present disclosure, and are not intended to limit the protection scope of the present disclosure. Any modifications, equivalent replacements, and improvements made within the spirit and principles of the present disclosure shall be included within the scope of the present disclosure.

1. A semiconductor device, comprising:
a substrate;
a gate layer on the substrate;
a first conduction layer and a second conduction layer, located on the gate layer and comprising a perovskite as a material;
a first source and a first drain, spaced apart from each other and connected with either end of the first conduction layer respectively; and
a second source and a second drain, spaced apart from each other and connected with either end of the second conduction layer respectively.

2. The semiconductor device of claim 1, wherein
the perovskite comprises an inorganic perovskite.

3. The semiconductor device of claim 1, wherein
the first source, the first drain, the first conduction layer and part of the gate layer constitute a transistor of a first conductive type;
the second source, the second drain, the second conduction layer and part of the gate layer constitute a transistor of a second conductive type; and
the first drain is in contact with the second drain so that the transistor of the first conductive type and the transistor of the second conductive type constitute an inverter.

4. The semiconductor device of claim 3, wherein
the first conductive type is an N-type, and the second conductive type is a P-type.

5. The semiconductor device of claim 4, wherein
a material of the first source and a material of the first drain comprise a low work function material; and
a material of the second source and a material of second drain comprise a high work function materials.

6. The semiconductor device of claim 1, wherein
a material of the gate layer comprises graphene.

7. The semiconductor device of claim 1, wherein the semiconductor device further comprises:
a dielectric layer, located on the gate layer and covering part of the gate layer; and
a first metal layer and a second metal layer that are stacked and formed on part of the gate layer not covered by the dielectric layer; wherein a material of the first metal layer is same as a material of the first source and a material of the first drain, a material of the second metal layer is same as a material of the second source and a material of the second drain.

8. The semiconductor device of claim 7, wherein the semiconductor device further comprises:
a passivation layer covering exposed surfaces of the first source, the first drain, the first conduction layer, the second source, the second drain, the second conduction layer and the second metal layer.

9. A method for manufacturing a semiconductor device, comprising:
provide a substrate;
forming a gate layer on the substrate;
forming a first conduction layer and a second conduction layer on the gate layer, wherein a material of the first conduction layer and a material of the second conduction layer comprise a perovskite;
forming a first source and a first drain that are spaced apart from each other at either end of the first conduction layer, wherein the first source and the first drain is connected with either end of the first conduction layer respectively; and
forming a second source and a second drain that are spaced apart from each other at either end of the second conduction layer, wherein the second source and the second drain is connected with either end of the second conduction layer respectively.

10. The method of claim 9, wherein
the perovskite comprises an inorganic perovskite.

11. The method of claim 9, wherein
constituting a transistor of a first conductive type by the first source, the first drain, the first conduction layer and part of the gate layer;
constituting a transistor of a second conductive type by the second source, the second drain, the second conduction layer and part of the gate layer; and
contacting the first drain with the second drain to constitute an inverter by the transistor of the first conductive type and the transistor of the second conductive type constitute.

12. The method of claim 11, wherein
the first conductive type is an N-type, and the second conductive type is a P-type.

13. The method of claim 12, wherein
a material of the first source and a material of the first drain comprise a low work function material; and
a material of the second source and a material of second drain comprise a high work function materials.

14. The method of claim 9, wherein
a material of the gate layer comprises graphene.

15. The method of claim 9, further comprising:
forming a dielectric layer covering part of the gate layer on the gate layer, after forming the gate layer;
forming a first metal layer on a part of the gate layer not covered by the dielectric layer in a same step of forming the first source and the first drain; wherein a material of the first metal layer is same as a material of the first source and a material of the first drain; and
forming a second metal layer on the first metal layer in a same step of forming the second source and the second drain; wherein a material of the second metal layer is same as a material of the second source and a material of the second drain.

16. The method of claim 15, further comprising:
forming a passivation layer, after forming the second source and the second drain; wherein the passivation layer covers exposed surfaces of the first source, the first drain, the first conduction layer, the second source, the second drain, the second conduction layer and the second metal layer.
